(19) United States
(12) Patent Application Publication
(10) Pub. No.: US 2025/0089160 A1
(43) Pub. Date: Mar. 13, 2025

(54) MULTILAYER SUBSTRATE

(71) Applicant: Murata Manufacturing Co., Ltd., Nagaokakyo-shi (JP)

(72) Inventors: TOMOKI YAMAMOTO, Nagaokakyo-shi (JP); Issei YAMAMOTO, Nagaokakyo-shi (JP)

(21) Appl. No.: 18/960,290

(22) Filed: Nov. 26, 2024

Related U.S. Application Data
(63) Continuation of application No. PCT/JP2023/018375, filed on May 17, 2023.

(30) Foreign Application Priority Data
May 27, 2022 (JP) 2022-087191

(51) Int. Cl. H05K 1/02; H05K 1/03; H05K 1/11

(52) U.S. Cl. CPC H05K 1/0298; H05K 1/0306; H05K 1/032; H05K 1/115; H05K 2201/0129; H05K 2201/096

(57) ABSTRACT

A multilayer substrate that includes: a first thermoplastic resin layer including a first main surface, a second main surface opposite to the first main surface, and a via hole penetrating from the first main surface to the second main surface; a ceramic layer in contact with the first main surface; an interlayer connection conductor in the via hole; a conductor portion on the ceramic layer and connected to the interlayer connection conductor; an intermetallic compound between the interlayer connection conductor and the conductor portion; and ceramic particles in the intermetallic compound, wherein the ceramic particles include first ceramic particles in contact with both the intermetallic compound and the conductor portion.

### CROSS REFERENCE TO RELATED APPLICATIONS

The present application is a continuation of International application No. PCT/JP2023/018375, filed May 17, 2023, which claims priority to Japanese Patent Application No. 2022-087191, filed May 27, 2022, the entire contents of each of which are incorporated herein by reference.

### TECHNICAL FIELD

The present disclosure relates to a multilayer substrate.

### BACKGROUND ART

Conventionally, modular components using multilayer substrates with built-in passive elements have been put to practical use. For example, a DC-DC converter module is known in which a switching integrated circuit (IC) chip and a chip capacitor are mounted on a multilayer substrate with a built-in coil as a passive element.

Known multilayer substrates used for such module components include a multilayer substrate in which ceramic substrates are laminated. In a multilayer substrate in which ceramic substrates are laminated, any of the ceramic substrates may warp. In order to solve such a problem, Patent Literature 1 discloses a multilayer substrate (module component) in which a substrate made of a thermoplastic resin (thermoplastic resin layer) is laminated on a multilayer substrate in which ceramic substrates are laminated.

In other words, Patent Literature 1 discloses a module component including: a ceramic multilayer substrate with a built-in passive component, a first terminal electrode on one main surface of the ceramic multilayer substrate, and a second terminal electrode on the other surface thereof, the first terminal electrode and the second terminal electrode being connected to the passive component; a first thermoplastic resin layer on the one main surface of the ceramic multilayer substrate, the first thermoplastic resin layer including a first wire connected to the first terminal electrode and a first land for mounting a surface-mounted component thereon; a second thermoplastic layer on the other main surface of the ceramic multilayer substrate, the second thermoplastic layer including a second wire connected to the second terminal electrode and a second land serving as a connection terminal to a mother board; and a surface-mounted component mounted on the first thermoplastic resin layer and connected to the first land of the first thermoplastic resin layer. The first thermoplastic resin layer and the second thermoplastic resin layer have different thicknesses, the first thermoplastic resin layer is thicker than the second thermoplastic resin layer, the ceramic multilayer substrate is a substrate including a non-glass-based low-temperature co-fired ceramic material, the first terminal electrode of the ceramic multilayer substrate and an interlayer conductor in the first thermoplastic resin layer are bonded by transient liquid phase diffusion bonding, and the second terminal electrode of the ceramic multilayer substrate and an interlayer conductor in the second thermoplastic resin layer are bonded by transient liquid phase diffusion bonding.

In Patent Literature 1, the terminal electrodes in the ceramic multilayer substrate and the interlayer conductors in the thermoplastic resin layers are bonded by transient liquid phase diffusion bonding.

Patent Literature 2 discloses an interlayer connection conductor connected to a conductive wiring layer. An intermetallic compound layer including an intermetallic compound is formed between the conductive wiring layer and the interlayer connection conductor.

The intermetallic compound layer is produced in such a way that a metal such as Sn or an Sn alloy of the interlayer connection conductor melts when heated and reacts with a metal (e.g., Cu) of the conductive wiring layer. In other words, the intermetallic compound layer is produced when transient liquid phase diffusion bonding occurs.

Patent Literature 1: JP 6819668 B

Patent Literature 2: WO 2019/003729

### SUMMARY OF THE DISCLOSURE

The multilayer substrate (module component) described in Patent Literature 1 also includes an intermetallic compound layer as disclosed in Patent Literature 2 between the conductor portion (terminal electrode) on the ceramic layer and the interlayer connection conductor (interlayer conductor) in the thermoplastic resin layer.

The conductor portion on the ceramic layer, the interlayer connection conductor in the thermoplastic resin layer, and the intermetallic compound layer have different linear expansion coefficients, so that thermal stress is likely to occur between them.

In particular, an intermetallic compound has low ductility and is thus less likely to absorb thermal stress and is prone to fracture.

The present disclosure has been made to solve the above problems, and an object of the present disclosure is to provide a multilayer substrate in which the metal compound between the conductor portion on the ceramic layer and the interlayer connection conductor in the thermoplastic resin layer is less prone to fracture, even when heated.

The present disclosure relates to a multilayer substrate including: a first thermoplastic resin layer including a first main surface, a second main surface opposite to the first main surface, and a via hole penetrating from the first main surface to the second main surface; a ceramic layer in contact with the first main surface; an interlayer connection conductor in the via hole; a conductor portion on the ceramic layer and connected to the interlayer connection conductor; an intermetallic compound between the interlayer connection conductor and the conductor portion; and ceramic particles in the intermetallic compound, wherein the ceramic particles include first ceramic particles in contact with both the intermetallic compound and the conductor portion.

The present disclosure provides a multilayer substrate in which the metal compound between the conductor portion on the ceramic layer and the interlayer connection conductor in the thermoplastic resin layer is less prone to fracture, even when heated.

### BRIEF DESCRIPTION OF THE DRAWINGS

FIG. 1A is a schematic cross-sectional view of an example of a multilayer substrate according to a first embodiment of the present disclosure.

FIG. 1B is an enlarged view of a dashed line area in FIG. 1A.

FIG. 2 is a schematic cross-sectional view of an example of an interlayer connection conductor and its surroundings of another example of the multilayer substrate according to the first embodiment of the present disclosure.

FIG. 3 is a schematic process diagram of an example of preparing LTCC green sheets in a method of producing the multilayer substrate according to the first embodiment of the present disclosure.

FIG. 4A is a schematic process diagram of an example of filling via holes of the LTCC green sheets in the method of producing the multilayer substrate according to the first embodiment of the present disclosure.

FIG. 4B is a schematic process diagram of an example of filling the via holes of the LTCC green sheets in the method of producing the multilayer substrate according to the first embodiment of the present disclosure.

FIG. 5 is a schematic process diagram of an example of forming electrode patterns on the LTCC green sheets in the method of producing the multilayer substrate according to the first embodiment of the present disclosure.

FIG. 6 is a schematic process diagram of an example of laminating the LTCC green sheets in the method of producing the multilayer substrate according to the first embodiment of the present disclosure.

FIG. 7 is a schematic process diagram of an example of firing an LTCC green sheet laminate in the method of producing the multilayer substrate according to the first embodiment of the present disclosure.

FIG. 8 is a schematic process diagram of an example of preparing thermoplastic resin layers in the method of producing the multilayer substrate according to the first embodiment of the present disclosure.

FIG. 9A is a schematic process diagram of an example of forming electrode patterns on the thermoplastic resin layers in the method of producing the multilayer substrate according to the first embodiment of the present disclosure.

FIG. 9B is a schematic process diagram of an example of forming the electrode patterns on the thermoplastic resin layers in the method of producing the multilayer substrate according to the first embodiment of the present disclosure.

FIG. 10A is a schematic process diagram of an example of filling via holes of the thermoplastic resin layers in the method of producing the multilayer substrate according to the first embodiment of the present disclosure.

FIG. 10B is a schematic process diagram of an example of filling the via holes of the thermoplastic resin layers in the method of producing the multilayer substrate according to the first embodiment of the present disclosure.

FIG. 11 is a schematic process diagram of an example of laminating the thermoplastic resin layers in the method of producing the multilayer substrate according to the first embodiment of the present disclosure.

FIG. 12A is a schematic process diagram of an example of laminating the multilayer ceramic layer and the multilayer thermoplastic resin layer in the method of producing the multilayer substrate according to the first embodiment of the present disclosure.

FIG. 12B is a schematic process diagram of an example of laminating the multilayer ceramic layer and the multilayer thermoplastic resin layer in the method of producing the multilayer substrate according to the first embodiment of the present disclosure.

FIG. 13A is an explanatory schematic diagram of an example of connection between an interlayer connection conductor and a first electrode by transient liquid phase diffusion bonding.

FIG. 13B is an explanatory schematic diagram of another example of the connection between the interlayer connection conductor and the first electrode by transient liquid phase diffusion bonding.

FIG. 13C is an explanatory schematic diagram of another example of the connection between the interlayer connection conductor and the first electrode by transient liquid phase diffusion bonding.

FIG. 13D is an explanatory schematic diagram of another example of the connection between the interlayer connection conductor and the first electrode by transient liquid phase diffusion bonding.

FIG. 14 is a schematic cross-sectional view of an example of an interlayer connection conductor and its surroundings of a multilayer substrate according to a second embodiment of the present disclosure.

FIG. 15 is a schematic cross-sectional view of an example of an interlayer connection conductor and its surroundings of a multilayer substrate according to a third embodiment of the present disclosure.

FIG. 16 is a schematic cross-sectional view of an example of an interlayer connection conductor and its surroundings of a multilayer substrate according to a fourth embodiment of the present disclosure.

FIG. 17 is a schematic cross-sectional view of an example of an interlayer connection conductor and its surroundings of a multilayer substrate according to a fifth embodiment of the present disclosure.

### DESCRIPTION OF THE PREFERRED EMBODIMENTS

Hereinafter, a multilayer substrate of the present disclosure is described.

The present disclosure is not limited to the following preferred embodiments, and may be suitably modified without departing from the gist of the present disclosure. Combinations of two or more preferred features described in the following preferred embodiments are also within the scope of the present disclosure.

A multilayer substrate of the present disclosure includes: a first thermoplastic resin layer including a first main surface, a second main surface opposite to the first main surface, and a via hole penetrating from the first main surface to the second main surface; a ceramic layer in contact with the first main surface; an interlayer connection conductor in the via hole; a conductor portion on the ceramic layer and connected to the interlayer connection conductor; an intermetallic compound between the interlayer connection conductor and the conductor portion; and ceramic particles in the intermetallic compound, wherein the ceramic particles include first ceramic particles in contact with both the intermetallic compound and the conductor portion.

The multilayer substrate of the present disclosure includes ceramic particles in the intermetallic compound.

This can reduce the difference between the linear expansion coefficient of the intermetallic compound and the linear expansion coefficient of the conductor portion on the ceramic layer. As a result, the thermal stress applied to the intermetallic compound can be reduced. This can prevent fracture of the intermetallic compound due to thermal stress.

When the multilayer substrate of the present disclosure is produced, the interlayer connection conductor and the conductor portion are connected by transient liquid phase diffusion bonding. At this time, the intermetallic compound is formed by reaction between the conductor portion and the liquid phase component of the interlayer connection conductor.

The presence of ceramic particles in the intermetallic compound indicates that the conductor portion contains ceramic particles when the multilayer substrate of the present disclosure is produced. The presence of ceramic particles in the conductor portion can reduce the contact area between the conductor portion and the liquid phase component of the interlayer connection conductor, thereby suppressing the reaction and preventing excessive formation of an intermetallic compound. In particular, when the conductor portion contains ceramic particles in an amount enough to sufficiently suppress the reaction, in the produced multilayer substrate, the ceramic particles include particles in contact with both the intermetallic compound and the conductor portion.

In the multilayer substrate of the present disclosure, the conductor portion may be an electrode or a via.

The multilayer substrate of the present disclosure can be widely used in electronic devices such as portable information terminals and digital cameras as a multilayer substrate with a built-in coil and as a multilayer substrate in a micro DC-DC converter

The following describes embodiments of the multilayer substrate of the present disclosure with reference to drawings.

### First Embodiment

First, a multilayer substrate according to a first embodiment of the present disclosure is described.

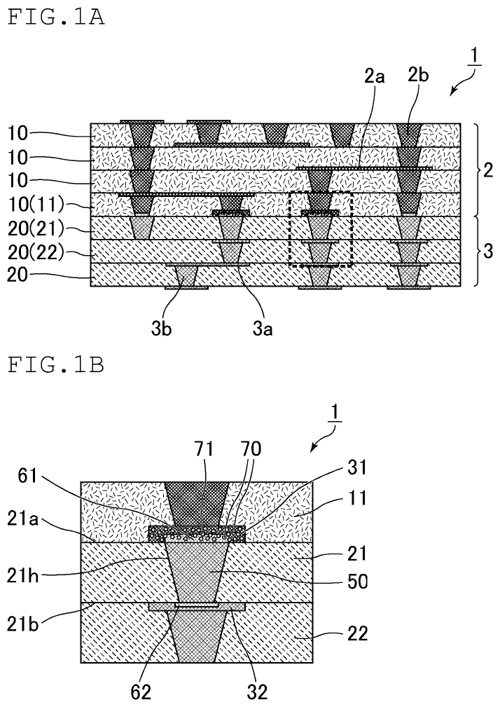

FIG. 1A is a schematic cross-sectional view of an example of the multilayer substrate according to the first embodiment of the present disclosure.

FIG. 1B is an enlarged view of a dashed line area in FIG. 1A.

A multilayer substrate 1 shown in FIG. 1A includes a multilayer ceramic layer 2 including a laminate of multiple ceramic layers 10 and a multilayer thermoplastic resin layer 3 including a laminate of multiple thermoplastic resin layers 20.

In the multilayer substrate 1 shown in FIG. 1A, the multilayer ceramic layer 2 is laminated on the multilayer thermoplastic resin layer 3.

As shown in FIG. 1A and FIG. 1B, the multilayer thermoplastic resin layer 3 includes a first thermoplastic resin layer 21 in contact with the multilayer ceramic layer 2.

As shown in FIG. 1B, the first thermoplastic resin layer 21 has a first main surface 21a, a second main surface 21b opposite to the first main surface 21a, and a via hole 21h penetrating from the first main surface 21a to the second main surface 21b.

As shown in FIG. 1A, the first main surface 21a of the first thermoplastic resin layer 21 is in contact with the multilayer ceramic layer 2.

As shown in FIG. 1A, the multilayer ceramic layer 2 includes a ceramic layer 11 in contact with the first main surface 21a of the first thermoplastic resin layer 21. A first electrode 31 is formed on a main surface of the ceramic layer 11 in contact with the first main surface 21a. The first electrode 31 is a conductor portion in the multilayer substrate of the present disclosure.

As shown in FIG. 1B, the first electrode 31 includes ceramic particles 70.

The multilayer thermoplastic resin layer 3 includes a second thermoplastic resin layer 22 in contact with the second main surface 21b.

A second electrode 32 is formed on a main surface of the second thermoplastic resin layer 22 in contact with the second main surface 21b.

An interlayer connection conductor 50 interconnecting the first electrode 31 and the second electrode 32 is disposed in the via hole 21h. An intermetallic compound 61 is formed between the interlayer connection conductor 50 and the first electrode 31. An intermetallic compound 62 is formed between the interlayer connection conductor 50 and the second electrode 32.

The via hole 21h has a tapered shape in which the opening in the first main surface 21a is larger than the opening in the second main surface 21b.

The via hole 21h having such a shape can improve the connection strength between the interlayer connection conductor 50 and the first electrode 31.

As shown in FIG. 1B, the multilayer substrate 1 includes the ceramic particles 70 in the intermetallic compound 61.

This can reduce the difference between the linear expansion coefficient of the intermetallic compound 61 and the linear expansion coefficient of the first electrode 31 on the ceramic layer 11. As a result, the thermal stress applied to the intermetallic compound 61 can be reduced. This can prevent fracture of the intermetallic compound 61 due to thermal stress.

In the multilayer substrate 1, the ceramic particles 70 include first ceramic particles 71 in contact with both the intermetallic compound 61 and the first electrode 31.

When the multilayer substrate 1 is produced, the interlayer connection conductor 50 and the first electrode 31 are connected by transient liquid phase diffusion bonding. At this time, the intermetallic compound 61 is formed by reaction between the first electrode 31 and the liquid phase component of the interlayer connection conductor 50.

The presence of the ceramic particles 70 in the intermetallic compound 61 indicates that the first electrode 31 contains the ceramic particles 70 when the multilayer substrate 1 is produced. The presence of the ceramic particles 70 in the first electrode 31 can reduce the contact area between the first electrode 31 and the liquid phase component of the interlayer connection conductor, thereby suppressing the reaction and preventing excessive formation of the intermetallic compound 61. In particular, when the first electrode 31 contains the ceramic particles 70 in an amount enough to sufficiently suppress the reaction, in the produced multilayer substrate 1, the ceramic particles 70 include particles in contact with both the intermetallic compound 61 and the first electrode 31.

As shown in FIG. 1A, the multilayer ceramic layer 2 may include electrode patterns 2a, vias 2b, etc., and the multilayer thermoplastic resin layer 3 may include electrode patterns 3a, vias 3b, etc.

The following describes preferred forms of the components of the multilayer substrate 1.

### (Interlayer Connection Conductor)

The interlayer connection conductor 50 is formed by filling the via hole 21h with a conductive paste containing a first metal powder and a second metal powder having a higher melting point than the first metal powder, and melting the conductive paste, followed by solidifying. The first metal powder in the conductive paste reacts with the first electrode 31 to form the intermetallic compound 61.

Preferably, the first metal powder is made of Sn or a Sn alloy and the second metal powder is made of a Cu—Ni alloy or a Cu—Mn alloy.

The conductive paste is specifically described in the section <Method of producing multilayer substrate> described below.

### (Multilayer Ceramic Layer)

The multilayer ceramic layer 2 includes the ceramic layers 10 including the ceramic layer 11.

The ceramic layers 10 may be made of, for example, a low temperature co-fired ceramic (LTCC) material. The low temperature co-fired ceramic material is a ceramic material that can be fired at a temperature of 1000° C. or lower and that can be co-fired with a low-resistive material such as Au, Ag, or Cu. Specific examples of the low temperature co-fired ceramic material include glass composite low temperature co-fired ceramic materials obtained by mixing a ceramic powder of alumina, zirconia, magnesia, forsterite, or the like with borosilicate glass; crystallized glass low temperature co-fired ceramic materials containing ZnO—MgO—Al₂O₃—SiO₂ crystallized glass; and non-glass low temperature co-fired ceramic materials containing BaO—Al₂O₃—SiO₂ ceramic powder, Al₂O₃—CaO—SiO₂—MgO—B₂O₃ ceramic powder, or the like.

The thickness of the ceramic layer 10 is preferably determined appropriately according to the design, and is preferably, for example, 5 μm to 100 μm.

Preferably, the first electrodes 31, the electrode patterns 2a, and the vias 2b are fired bodies of a conductive paste including a conductive powder, a plasticizer, and a binder.

Preferably, the first electrodes 31, the electrode patterns 2a, and the vias 2b are fired bodies of copper (Cu) and an alloy thereof.

The first electrodes 31, the electrode patterns 2a, and the vias 2b may contain silver (Ag), aluminum (Al), nickel (Ni), stainless steel (SUS), gold (Au), an alloy of any of these, or the like.

The first electrodes 31, the electrode patterns 2a, and the vias 2b may be made of the same material or different materials.

The thickness of the first electrode 31 is preferably determined appropriately according to the design, and is preferably, for example, 5 μm to 20 μm. Herein, the “thickness of the first electrode” refers to the maximum thickness of the first electrode.

### (Ceramic Particle)

The ceramic particles 70 may be formed by firing a glass component and a ceramic material or by firing a ceramic component obtained by calcining a glass component and a ceramic material.

The glass component may be borosilicate glass, ZnO—MgO—Al₂O₃—SiO₂ crystallized glass, or the like.

The ceramic particles 70 may contain the glass component in an amount of 50% by weight or more.

Examples of the ceramic material include alumina, zirconia, titania, quartz, barium titanate, silicon carbide, zinc oxide, and forsterite. Preferred of these is alumina.

The ceramic particles 70 may also include alumina in an amount of 50% by mass or more.

The ceramic particles 70 may be made of the same material as a material of the ceramic layer 11.

The ceramic particles 70 preferably have an average particle size of 0.5 μm to 3 μm.

The percentage of an area occupied by the ceramic particles 70 in a cross section of the intermetallic compound 61 in a direction perpendicular to the first main surface 21a of the multilayer substrate 1 is preferably 0.1% to 20.0%, more preferably 1.0% to 10.0%.

If the percentage of the area is lower than 0.1%, the proportion of ceramic particles is small, making it difficult to reduce the difference between the linear expansion coefficient of the intermetallic compound and the linear expansion coefficient of the first electrode.

If the percentage of the area is higher than 20.0%, the proportion of ceramic particles is high, the contact area between the first electrode and the intermetallic compound is small, and the electrical resistance is likely to increase.

The percentage of the area in the cross section of the intermetallic compound in the direction perpendicular to the first main surface is measured by the following method.

First, an image of the cross section of the intermetallic compound in the direction perpendicular to the first main surface of the multilayer substrate is taken with a scanning electron microscope (SEM).

A 20 μm (length)×20 μm (width) area is freely selected in the image. In the area, the percentage of an area occupied by the ceramic particles is calculated.

This calculation of the percentage of the area occupied by the ceramic particles is performed on three areas.

The percentages of the ceramic particles in these areas are averaged to determine the “percentage of the area occupied by the ceramic particles in the cross section of the intermetallic compound in the direction perpendicular to the first main surface.”

In the cross section of the intermetallic compound in the direction perpendicular to the first main surface in the multilayer substrate 1, lines defining interfaces between the intermetallic compound and the first electrode (conductor portion), which are referred to as first lines, and lines defining interfaces between the intermetallic compound and the first ceramic particles, which are referred to as second lines, satisfy the condition that the percentage of a total length of the second lines to a total length of the first lines and the second lines is preferably 0.1% to 50.0%, more preferably 1.0% to 20.0%.

If the percentage is lower than 0.1%, the proportion of ceramic particles is low. Thus, when the first electrode and the interlayer connection conductor are connected in the production of the multilayer substrate, the contact area between the first electrode and the liquid phase component of the interlayer connection conductor is less likely to be small, and the intermetallic compound is likely to spread.

If the percentage is higher than 50.0%, the number of first ceramic particles is large, the contact area between the first electrode and the intermetallic compound is small, and the electrical resistance is likely to increase.

The percentage of the total length of the second lines to the total length of the first lines and the second lines is measured by the following method.

First, an image of the cross section including the first electrode and the intermetallic compound in the direction perpendicular to the first main surface of the multilayer substrate is taken with a scanning electron microscope (SEM).

In the image of the cross section, lines defining the interfaces between the intermetallic compound and the first electrode are referred to as first lines, and lines defining the interfaces between the intermetallic compound and the first ceramic particles are referred to as second lines. The length of the first lines and the lengths of the second lines are calculated from the number of pixels of the first lines and the number of pixels of the second lines, respectively.

The value obtained by dividing the total length of the second lines by the total length of the first lines and the second lines is calculated.

The same operation is performed three times on different cross sections.

The resulting values are averaged to obtain the “percentage of the total length of the second lines to the total length of the first lines and the second lines.”

### (Multilayer Thermoplastic Resin Layer)

The multilayer thermoplastic resin layer 3 includes the thermoplastic resin layers 20 including the first thermoplastic resin layer 21 and the second thermoplastic resin layer 22.

Examples of materials of each thermoplastic resin layer 20 include liquid crystal polymers (LCP), thermoplastic polyimide resins, polyether ether ketone (PEEK) resins, and polyphenylene sulfide (PPS) resins.

Of these, liquid crystal polymers (LCP) are preferred. Liquid crystal polymers have a lower water absorption rate than other thermoplastic resins, and can prevent variations in electrical characteristics and deterioration in electrical connection reliability.

The thickness of the thermoplastic resin layer 20 is preferably determined appropriately according to the design, and is preferably, for example, 10 μm to 100 μm.

As shown in FIG. 1B, the via hole 21h in the first thermoplastic resin layer 21 has a tapered shape.

Preferably, the tapered shape has an inclination angle that changes stepwise. In this case, the inclination angle may change in two steps, or three or more steps.

In the multilayer substrate of the present disclosure, each via hole may have a tapered shape in which the opening in the first main surface is smaller than the opening in the second main surface, or may have a cylindrical shape in which the opening in the first main surface and the opening in the second main surface have the same size.

The opening of the via hole 21h in the first main surface 21a preferably has a diameter of 20 μm to 200 μm.

The opening of the via hole 21h in the first main surface 21b preferably has a diameter of 20 μm to 200 μm.

Examples of materials of the second electrodes 32 and the electrode patterns 3a include copper (Cu), silver (Ag), aluminum (Al), nickel (Ni), stainless steel (SUS), and alloys thereof. The second electrodes 32 and the electrode patterns 3a can be formed by laminating a metal foil on the thermoplastic resin layer 20 and patterning it by a technique such as etching.

The second electrodes 32 and the electrode patterns 3a may be made of the same material or different materials.

Preferred materials of the vias 2b are the same as the preferred materials of the interlayer connection conductors 50.

The thickness of the second electrode 32 is preferably determined appropriately according to the design, and is preferably, for example, 3 μm to 40 μm.

Next, another example of the multilayer substrate according to the first embodiment of the present disclosure is described.

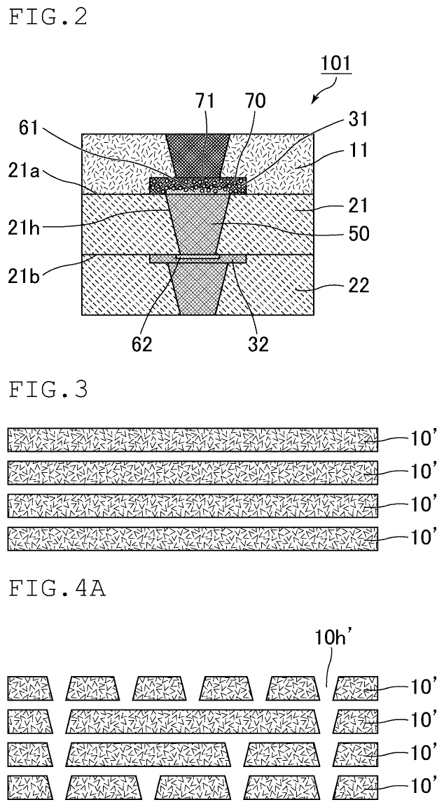

FIG. 2 is a schematic cross-sectional view of an example of an interlayer connection conductor and its surroundings of another example of the multilayer substrate according to the first embodiment of the present disclosure.

A multilayer substrate 101 shown in FIG. 2 has the same structure as the multilayer substrate 1 described above, except that the intermetallic compound 61 is interposed partially between the first ceramic particles 71 and the first electrode 31.

When the intermetallic compound 61 is interposed partially between the first ceramic particles 71 and the first electrode 31, the connection strength between the intermetallic compound 61 and the first electrode 31 can be improved, and the connection reliability can be improved, owing to the anchor effect.

An example of a method for forming the intermetallic compound 61 to interpose the intermetallic compound 61 partially between the first ceramic particles 71 and the first electrode 31 is a method of adjusting the temperature and pressure when the interlayer connection conductor 50 and the first electrode 31 are connected in the production of the multilayer substrate 101.

Also, the structure shown in FIG. 2 can be formed by adjusting the average particle size of the ceramic particles 70 and the composition of the interlayer connection conductor 50.

Next, a method of producing the multilayer substrate according to the first embodiment of the present disclosure is described. The following describes the case where the ceramic layers include an LTCC material.

### <Preparation of LTCC Green Sheet>

FIG. 3 is a schematic process diagram of an example of preparing LTCC green sheets in a method of producing the multilayer substrate according to the first embodiment of the present disclosure.

In the production of the multilayer substrate according to the first embodiment of the present disclosure, first, as shown in FIG. 3, multiple LTCC green sheets 10′ are prepared.

The LTCC green sheets 10′ can be prepared in the following manner.

First, a ceramic powder, a binder, and a plasticizer are mixed in any amounts to prepare a slurry. The ceramic powder may include any of the preferred materials described for the ceramic layer 10. The binder and the plasticizer may each be a conventionally known one.

Next, the slurry is applied to carrier films and formed into sheets to obtain the LTCC green sheets 10′.

The slurry may be applied with a lip coater or a doctor blade. In this case, the thickness of each LTCC green sheet 10′ is preferably, for example, 5 μm to 100 μm.

### <Filling of Via Hole of LTCC Green Sheet>

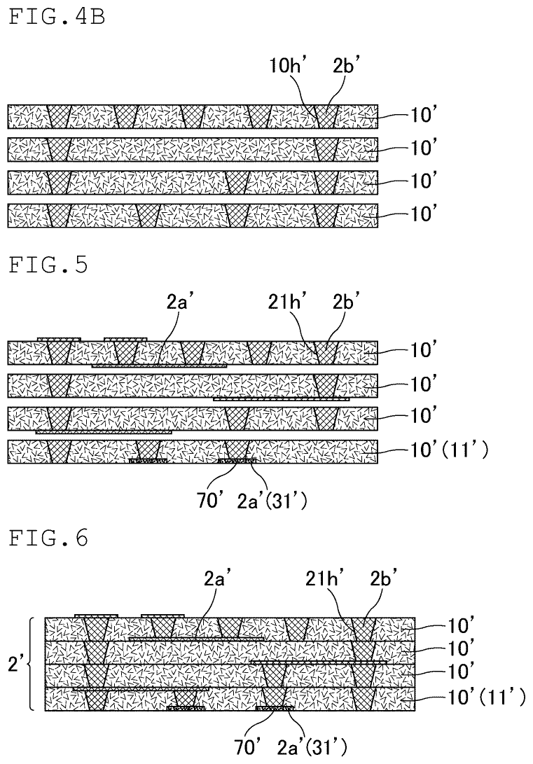

FIG. 4A and FIG. 4B are each a schematic process diagram of an example of filling via holes of the LTCC green sheets in the method of producing the multilayer substrate according to the first embodiment of the present disclosure.

Next, as shown in FIG. 4A, via holes 10h′ are formed in the LTCC green sheets 10′. The via holes 10h′ may be formed by any method and can be formed using a mechanical punch, a CO₂ laser, a UV laser, or the like.

The sizes of the openings of each via hole 10h′ are not limited, and are each preferably 20 μm to 200 μm.

Next, as shown in FIG. 4B, the via holes 10h′ are filled with a conductive paste 2b′ containing a conductive powder, a plasticizer, and a binder.

The conductive paste 2b′ may contain the ceramic powder of the LTCC green sheets 10′. When the conductive paste 2b′ contains such a ceramic powder, the difference in shrinkage between the LTCC green sheets 10′ and the conductive paste 2b′ is small. As a result, cracking and the like can be prevented from occurring during firing of the LTCC green sheets 10′ and the conductive paste 2b′.

### <Formation of Electrode Pattern on LTCC Green Sheet>

FIG. 5 is a schematic process diagram of an example of forming electrode patterns on the LTCC green sheets in the method of producing the multilayer substrate according to the first embodiment of the present disclosure.

Next, as shown in FIG. 5, electrode patterns 2a′ are printed on the surfaces of the LTCC green sheets 10′ using a conductive paste containing a conductive powder, a plasticizer, and a binder. Examples of the printing method include screen printing, inkjet printing, and gravure printing.

In a later step, the LTCC green sheets 10′ are laminated to form a laminate. Among the electrode patterns 2a′ on the outermost LTCC green sheet 10′ in the laminate, one or more of the electrode patterns (indicated by the symbol 31′ in FIG. 5) serve as the first electrodes connected to the interlayer connection conductors in the multilayer substrate to be produced.

Furthermore, the LTCC green sheet 10′ on which the electrode patterns 31′ are formed serves as the ceramic substrate in contact with the first main surface of the first thermoplastic resin layer in the multilayer substrate to be produced.

In this step, unfired ceramic particles 70′ are mixed into a conductive paste for forming the electrode patterns 31′. Preferably, the unfired ceramic particles 70′ include a glass composition and a ceramic material or include a ceramic component obtained by calcining a glass composition and a ceramic material.

In the inorganic solid content of the conductive paste for forming the electrode patterns 31′, the amount of the unfired ceramic particles 70′ is preferably 0.1% by weight to 20% by weight.

If the amount is less than 0.1% by weight, the amount of ceramic particles formed through a subsequent step is small. Thereby, the effect of reducing the linear expansion coefficient of the intermetallic compound is less likely to be obtained, and the effect of preventing formation of an intermetallic compound is less likely to be obtained.

### <Lamination of LTCC Green Sheet>

FIG. 6 is a schematic process diagram of an example of laminating the LTCC green sheets in the method of producing the multilayer substrate according to the first embodiment of the present disclosure.

Next, as shown in FIG. 6, the LTCC green sheets 10′ are laminated to form an LTCC green sheet laminate 2′. The number of the sheets to be laminated is preferably determined appropriately according to the design.

Thereafter, the LTCC green sheet laminate 2′ is placed in a mold and pressure-bonded. The pressure and temperature are preferably set freely according to the design.

### <Firing of LTCC Green Sheet Laminate>

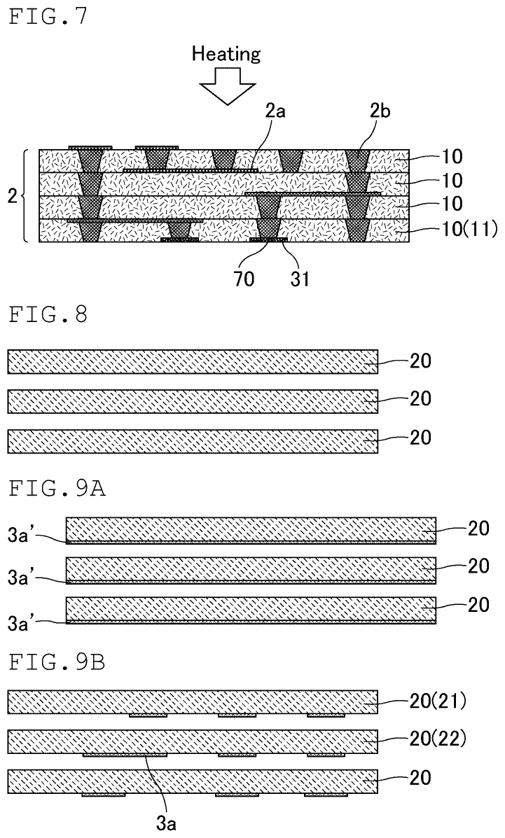

FIG. 7 is a schematic process diagram of an example of firing an LTCC green sheet laminate in the method of producing the multilayer substrate according to the first embodiment of the present disclosure.

Next, as shown in FIG. 7, the LTCC green sheet laminate 2′ is heated and fired to form the multilayer ceramic layer 2.

In this step, the conductive paste 2b′ is fired into the vias 2b, and the electrode patterns 2a′ and the electrode patterns 31′ are fired into the electrode patterns 2a and the first electrodes 31. The unfired ceramic particles 70′ become the ceramic particles 70.

The firing may be performed using a firing furnace such as a batch furnace or a belt furnace. The firing may be performed under any conditions and is preferably performed at 800° C. to 1000° C.

When the conductive paste 2b′, the electrode patterns 2a′, and the electrode patterns 31′ contain copper (Cu), the firing is preferably performed in a reducing atmosphere.

### <Preparation of Thermoplastic Resin Layer>

FIG. 8 is a schematic process diagram of an example of preparing thermoplastic resin layers in the method of producing the multilayer substrate according to the first embodiment of the present disclosure.

Next, as shown in FIG. 8, the sheet-like thermoplastic resin layers 20 are prepared. The preferred materials of the thermoplastic resin layers 20 have already been described and are thus omitted here.

The thickness of each thermoplastic resin layer 20 is preferably 10 μm to 100 μm.

### <Formation of Electrode Pattern on Thermoplastic Resin Layer>

FIG. 9A and FIG. 9B are each a schematic process diagram of an example of forming electrode patterns on the thermoplastic resin layers in the method of producing the multilayer substrate according to the first embodiment of the present disclosure.

Next, as shown in FIG. 9A, a metal foil 3a′ is laminated on the main surfaces of the thermoplastic resin layers 20. Next, as shown in FIG. 9B, the metal foil 3a′ is patterned by etching or the like to form the electrode patterns 3a.

The metal foil 3a′ may be made of copper (Cu), silver (Ag), aluminum (Al), nickel (Ni), stainless steel (SUS), or an alloy of any of these.

Preferably, the metal foil 3a′ has a shiny surface as one main surface and a matte surface as the other surface. The metal foil 3a′ is preferably laminated such that the matte surface is in contact with the main surface of each thermoplastic resin layer 20.

The matte surface of the metal foil 3a′ is a roughened surface, and preferably has a surface roughness Rz (JIS B 0601-2001) of 1 μm to 15 μm.

In a later step, the thermoplastic resin layers 20 are laminated to form a laminate. The outermost thermoplastic resin layer 20 in the laminate serves as the first thermoplastic resin layer 21. Another thermoplastic resin layer 20 in contact with the second main surface 21b of the first thermoplastic resin layer 21 serves as the second thermoplastic resin layer 22.

Among the electrode patterns 2a on the main surface of the second thermoplastic resin layer 22 facing the second main surface 21b, one or more of the electrode patterns serve as the second electrodes 32 connected to the interlayer connection conductors in the multilayer substrate to be produced.

### <Filling of Via Hole of Thermoplastic Resin Layer>

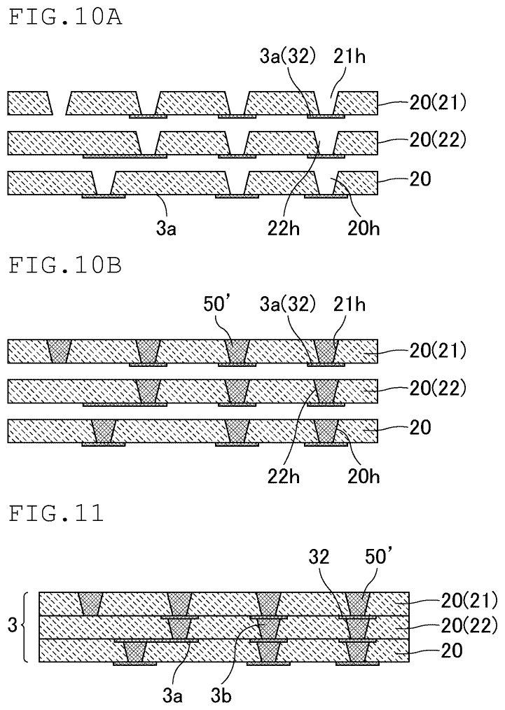

FIG. 10A and FIG. 10B are each a schematic process diagram of an example of filling via holes of the thermoplastic resin layers in the method of producing the multilayer substrate according to the first embodiment of the present disclosure.

Next, as shown in FIG. 10A, the via holes 21h, via holes 22h, and via holes 20h are formed in the first thermoplastic resin layer 21, the second thermoplastic resin layer 22, and another thermoplastic resin layer 20, respectively.

The via holes may be formed by any method and can be formed using a mechanical punch, a CO2 laser, a UV laser, or the like.

After the via holes are formed, a desmear treatment is preferably performed by an oxygen plasma treatment, a corona discharge treatment, or a potassium permanganate treatment.

The sizes of the openings of each of the via holes 21h, 22h, and 20h are not limited, and are each preferably 20 μm to 200 μm.

For the convenience of showing the internal structure in a plan view, FIG. 10A includes a portion in which a via hole is formed directly under the electrode pattern 3a and the via hole does not appear to be formed as a through hole. However, actually, the positions where the electrode patterns 3a are formed and the positions where the via holes are formed are shifted in the depth direction of the paper, and the via holes are formed as through holes.

Next, as shown in FIG. 10B, the via holes 21h, 22h and 20h are filled with a conductive paste 50′ that is a precursor of the interlayer connection conductor.

The filling may be performed by any method, and can be performed by screen printing, vacuum printing, or the like.

The conductive paste 50′ contains a first metal powder and a second metal powder having a melting point higher than that of the first metal powder.

Preferably, the first metal powder in the conductive paste 50′ is made of Sn or a Sn alloy and the second metal powder in the conductive paste 50′ is made of a Cu—Ni alloy or a Cu—Mn alloy. The conductive paste 50′ may be, for example, a conductive paste disclosed in JP 5146627 B. Hereinafter, the metal component in the first metal powder is also referred to as a “first metal”, and the metal component in the second metal powder is also referred to as a “second metal”.

Examples of the Sn or Sn alloy include a simple substance of Sn and alloys containing Sn and at least one selected from the group consisting of Cu, Ni, Ag, Au, Sb, Zn, Bi, In, Ge, Al, Co, Mn, Fe, Cr, Mg, Mn, Pd, Si, Sr, Te, and P. The Sn content of the Sn alloy is preferably 70 wt % or more, more preferably 85 wt % or more.

The proportion of Ni in the Cu—Ni alloy is preferably 10 wt % to 15 wt %. The proportion of Mn in the Cu—Mn alloy is preferably 10 wt % to 15 wt %. This enables supply of a necessary and sufficient amount of Ni or Mn to produce a desired intermetallic compound. When the proportion of Ni in the Cu—Ni alloy and the proportion of Mn in the Cu—Mn alloy are each less than 10 wt %, a portion of Sn tends to remain unreacted without being entirely converted into an intermetallic compound. Also when the proportion of Ni in the Cu—Ni alloy and the proportion of Mn in the Cu—Mn alloy are each more than 15 wt %, a portion of Sn tends to remain unreacted without being entirely converted into an intermetallic compound.

The Cu—Ni alloy or the Cu—Mn alloy may contain both Mn and Ni or may contain a third component such as P.

The first metal powder and the second metal powder each preferably have an arithmetic mean particle size of 3 μm to 10 μm. When the mean particle size of each metal powder is too small, it increases the production cost. In addition, such a metal powder tends to be oxidized quickly and interfere with a reaction. In contrast, when the mean particle size of each metal powder is too large, it is difficult to fill each via hole with the conductive paste 50′.

The proportion of the second metal in the metal components in the conductive paste 50′ is preferably 30 wt % or more. In other words, the proportion of the first metal in the metal components in the conductive paste 50′ is preferably 70 wt % or less. In this case, the residual proportion of the first metal such as Sn is further decreased, allowing for an increase in the proportion of the intermetallic compound.

The proportion of the metal components in the conductive paste 50′ is preferably 70 wt % to 95 wt %. When the proportion of the metal components is more than 95 wt %, it is difficult to obtain a low-viscosity conductive paste 50′ having excellent filling properties. In contrast, when the proportion of the metal components is less than 70 wt %, a flux component tends to remain.

The conductive paste 50′ preferably contains a flux component. The flux component may be any of various known flux components used as materials of common conductive pastes, and contains a resin. Examples of components other than the resin include vehicles, solvents, thixotropic agents, and activators.

The resin preferably includes at least one thermosetting resin selected from the group consisting of epoxy resins, phenolic resins, polyimide resins, silicone resins or modified resins thereof, and acrylic resins, or at least one thermoplastic resin selected from the group consisting of polyamide resins, polystyrene resins, polymethacrylic resins, polycarbonate resins, and cellulose-based resins.

Examples of the vehicles include rosin-based resins and synthetic resins, which are obtained from rosin and rosin derivatives such as modified rosins or the like, and mixtures thereof. Examples of the rosin-based resins obtained from rosin and rosin derivatives such as modified rosins include gum rosin, tall rosin, wood rosin, polymerized rosin, hydrogenated rosin, formylated rosin, rosin ester, rosin-modified maleic acid resin, rosin-modified phenolic resin, rosin-modified alkyd resin, and other various rosin derivatives. Examples of the synthetic resins obtained from rosin and rosin derivatives such as modified rosins include polyester resins, polyamide resins, phenoxy resins, and terpene resins.

Examples of the solvents include alcohols, ketones, esters, ethers, and aromatic hydrocarbons. Specific examples include benzyl alcohol, ethanol, isopropyl alcohol, butanol, diethylene glycol, ethylene glycol, glycerol, ethyl cellosolve, butyl cellosolve, ethyl acetate, butyl acetate, butyl benzoate, diethyl adipate, dodecane, tetradecene, α-terpineol, terpineol, 2-methyl-2,4-pentanediol, 2-ethylhexanediol, toluene, xylene, propylene glycol monophenyl ether, diethylene glycol monohexyl ether, ethylene glycol monobutyl ether, diethylene glycol monobutyl ether, diisobutyl adipate, hexylene glycol, cyclohexane dimethanol, 2-terpinyloxy ethanol, 2-dihydroterpinyloxy ethanol, and mixtures thereof. Preferred among these are terpineol, ethylene glycol monobutyl ether, diethylene glycol monoethyl ether, and diethylene glycol monobutyl ether.

Specific examples of the thixotropic agents include hydrogenated castor oil, carnauba wax, amides, hydroxy fatty acids, dibenzylidene sorbitol, bis(p-methylbenzylidene)sorbitol, beeswax, stearamide, and ethylenebisamide hydroxystearate. The thixotropic agents can also be those thixotropic agents to which the following additives are added as needed: fatty acids such as caprylic acid, lauric acid, myristic acid, palmitic acid, stearic acid, and behenic acid; hydroxy fatty acids such as 1,2-hydroxystearic acid; antioxidants; surfactants; and amines.

Examples of the activators include amine hydrohalides, organohalogen compounds, organic acids, organic amines, and polyhydric alcohols.

Examples of the amine hydrohalides include diphenylguanidine hydrobromide, diphenylguanidine hydrochloride, cyclohexylamine hydrobromide, ethylamine hydrochloride, ethylamine hydrobromide, diethylaniline hydrobromide, diethylaniline hydrochloride, triethanolamine hydrobromide, and monoethanolamine hydrobromide.

Examples of the organohalogen compounds include chlorinated paraffins, tetrabromoethane, dibromopropanol, 2,3-dibromo-1,4-butanediol, 2,3-dibromo-2-butene-1,4-diol, and tris(2,3-dibromopropyl)isocyanurate.

Examples of the organic acids include malonic acid, fumaric acid, glycolic acid, citric acid, malic acid, succinic acid, phenyl succinic acid, maleic acid, salicylic acid, anthranilic acid, glutaric acid, suberic acid, adipic acid, sebacic acid, stearic acid, abietic acid, benzoic acid, trimellitic acid, pyromellitic acid, and dodecanoic acid.

Examples of the organic amines include monoethanolamine, diethanolamine, triethanolamine, tributylamine, aniline, and diethylaniline.

Examples of the polyhydric alcohols include erythritol, pyrogallol, and ribitol.

### <Lamination of Thermoplastic Resin Layer>

FIG. 11 is a schematic process diagram of an example of laminating the thermoplastic resin layers in the method of producing the multilayer substrate according to the first embodiment of the present disclosure.

Next, as shown in FIG. 11, the first thermoplastic resin layer 21, the second thermoplastic resin layer 22, and the another thermoplastic resin layer 20 are laminated to form the multilayer thermoplastic resin layer 3.

### <Lamination of Multilayer Ceramic Layer and Multilayer Thermoplastic Resin Layer>

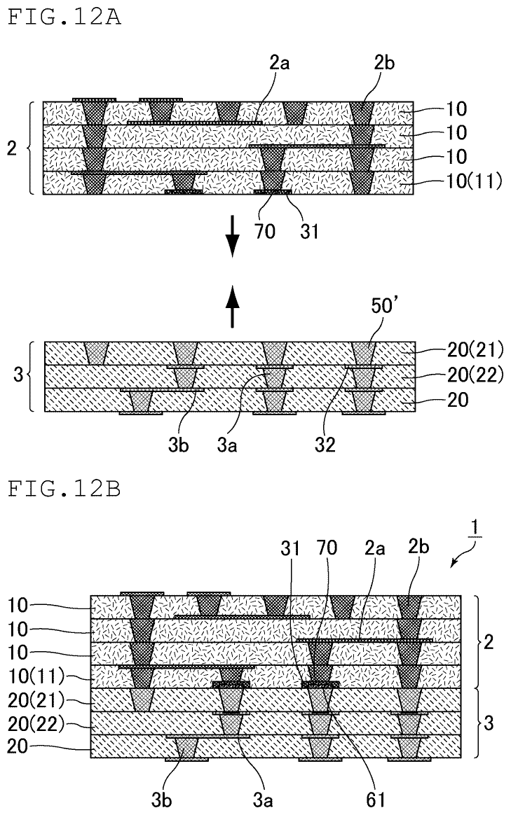

FIG. 12A and FIG. 12B are each a schematic process diagram of an example of laminating the multilayer ceramic layer and the multilayer thermoplastic resin layer in the method of producing the multilayer substrate according to the first embodiment of the present disclosure.

Next, as shown in FIG. 12A, the multilayer ceramic layer 2 is laminated on the multilayer thermoplastic resin layer 3. The multilayer thermoplastic resin layer 3 and the multilayer ceramic layer 2 are positioned so that the conductive paste 50′ in the first thermoplastic resin layer 21 of the multilayer thermoplastic resin layer 3 is in contact with the exposed surfaces of the first electrodes 31 on the outermost ceramic layer 11 of the multilayer ceramic layer 2.

Thereafter, as shown in FIG. 12B, the multilayer thermoplastic resin layer 3 and the multilayer ceramic layer 2 are integrated by application of pressure and heat.

The first thermoplastic resin layer 21 conforms to the irregularities on the surface of the ceramic layer 11 so that the multilayer thermoplastic resin layer 3 and the multilayer ceramic layer 2 are closely attached to each other due to the anchor effect.

This step is performed by treatment at 230° C. to 350° C. under atmospheric pressure, for example.

In this step, the conductive paste 50′ is melted and then solidified to become the interlayer connection conductors 50.

The interlayer connection conductors 50 and the first electrodes 31 are connected by transient liquid phase diffusion bonding. At this time, the intermetallic compound 61 is formed between the interlayer connection conductors 50 and the first electrodes 31.

The transient liquid phase diffusion bonding is described with reference to the drawings.

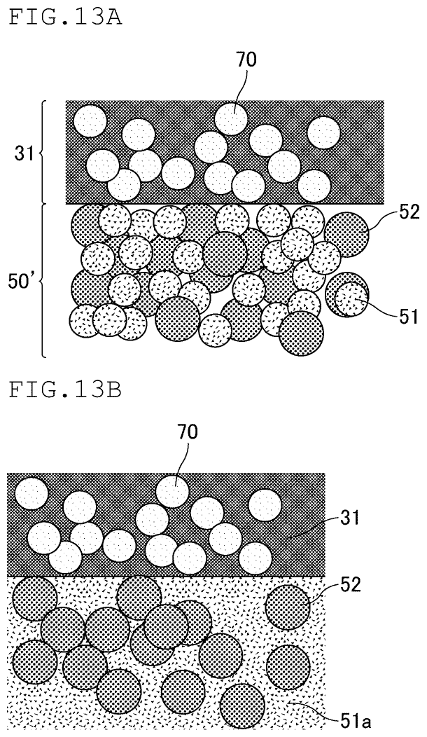

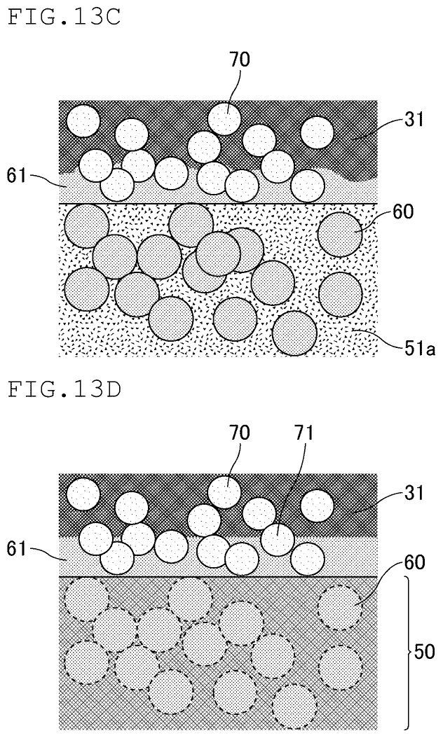

FIG. 13A to FIG. 13D are each an explanatory schematic diagram of an example of the connection between an interlayer connection conductor with a first electrode by transient liquid phase diffusion bonding.

As shown in FIG. 13A, the conductive paste 50′ contains a first metal powder 51 and a second metal powder 52 having a melting point higher than that of the first metal powder 51. The conductive paste 50′ is in contact with the first electrode 31.

As shown in FIG. 13B, when the conductive paste 50′ is heated in this state and reaches the melting point of the first metal powder 51, the first metal powder 51 melts and becomes a liquid phase first metal 51a.

Thereafter, as heat is continued to be applied, the liquid phase first metal 51a reacts with the second metal powder 52 to form the intermetallic compound 60, as shown in FIG. 13C.

Moreover, the liquid phase first metal 51a spreads in a diffusive manner over the first electrode 31, and reacts with the metal of the first electrode 31 to form the intermetallic compound 61.

The first electrode 31 contains the ceramic particles 70. The ceramic particles 70 suppress the diffusion of the liquid phase first metal 51a. This can prevent formation of the intermetallic compound 61 over a wide area.

Thereafter, when the heating is terminated and the temperature is lowered, the liquid phase first metal 51a solidifies to become the interlayer connection conductor 50, as shown in FIG. 13D. At this time, the ceramic particles 70 include particles that will become the first ceramic particles 71 in contact with both the first electrode 31 and the intermetallic compound 61.

In FIG. 13D, for the sake of convenience, the outline of the intermetallic compound 60 derived from the second metal powder 52 is shown by a dashed line, but actually, the boundary is not clear and the intermetallic compound 60 does not appear to be particulate.

In this step, the interlayer connection conductor 50 and the second electrode 32 are connected by transient liquid phase diffusion bonding, so that the intermetallic compound 61 is also formed between the interlayer connection conductor 50 and the second electrode 32.

The multilayer substrate 1 can be produced through the above steps.

### Second Embodiment

Next, a multilayer substrate according to a second embodiment of the present disclosure is described.

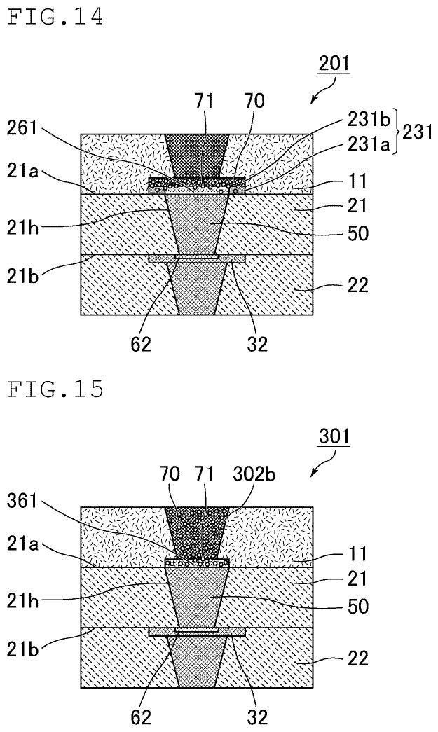

FIG. 14 is a schematic cross-sectional view of an example of an interlayer connection conductor and its surroundings of the multilayer substrate according to the second embodiment of the present disclosure.

A multilayer substrate 201 shown in FIG. 14 has the same structure as the multilayer substrate 1 according to the first embodiment, except for the following points.

In the multilayer substrate 201, a first electrode 231 includes a first conductor layer 231a facing the first thermoplastic resin layer 21 and a second conductor layer 231b laminated on the first conductor layer 231a.

The weight percentage of the ceramic particles 70 in the first conductor layer 231a is lower than the weight percentage of the ceramic particles 70 in the second conductor layer 231b. The first conductor layer 231a may not contain the ceramic particles 70.

When the first conductor layer 231a contains the ceramic particles 70, the ratio of the weight of the ceramic particles 70 in the first conductor layer 231a to the weight of the ceramic particles 70 in the second conductor layer 231b, “weight of ceramic particles in first conductor layer/weight of ceramic particles in second conductor layer”, is preferably higher than 0 and not higher than 0.7.

In the multilayer substrate 201, the thickness of the first conductive layer 231a is preferably 5 μm to 10 μm. The thickness of the second conductive layer 231b is preferably 5 μm to 10 μm.

The multilayer substrate 201 having such a structure can be produced by a method similar to the method of producing the multilayer substrate according to the first embodiment of the present disclosure, except that the section <Firing of LTCC green sheet laminate> described above is changed as follows.

Specifically, when the first electrode 231 is formed in the section <Firing of LTCC green sheet laminate> described above, a conductive paste containing a large amount of unfired ceramic particles is printed, and then a conductive paste containing a small amount of unfired ceramic particles or no unfired ceramic particles is printed thereon.

The conductive paste containing a large amount of unfired ceramic particles preferably contains the same calcined ceramic powder as that in the LTCC green sheets in an amount of 5% by volume to 70% by volume of the inorganic solid content of the conductive paste.

The conductive paste containing a small amount of unfired ceramic particles preferably contains the same calcined ceramic powder as that in the LTCC green sheets and/or alumina in an amount of 2% by volume or more of the inorganic solid content of the conductive paste.

In the production of the multilayer substrate 201 in this manner, an intermetallic compound 261 is formed as follows when the interlayer connection conductor 50 and the first electrode 231 are connected by transient liquid phase diffusion bonding.

When the interlayer connection conductor 50 and the first electrode 231 are connected by transient liquid phase diffusion bonding, the first conductor layer 231a quickly becomes the intermetallic compound 261 because the weight percentage of the ceramic particles 70 in the first conductor layer 231a is low.

When the intermetallic compound 261 reaches the second conductor layer 231b, the second conductor layer 231b is less likely to become the intermetallic compound 261 because the weight percentage of the ceramic particles 70 in the second conductor layer 231b is high.

In other words, the intermetallic compound 261 is less likely to be formed at the boundary between the first conductor layer 231a and the second conductor layer 231b.

Thus, the range in which the intermetallic compound 261 is formed can be controlled by adjusting the weight percentages of the ceramic particles 70 in the first conductor layer 231a and the second conductor layer 231b, the thicknesses of the first conductor layer 231a and the second conductor layer 231b, and the like.

For this reason, the intermetallic compound 261 can be prevented from diffusing excessively in the thickness direction.

Since the first conductor layer 231a easily becomes the intermetallic compound 261, the interlayer connection conductor 50 and the first electrode 231 can be reliably connected.

### Third Embodiment

Next, a multilayer substrate according to a third embodiment of the present disclosure is described.

FIG. 15 is a schematic cross-sectional view of an example of an interlayer connection conductor and its surroundings of the multilayer substrate according to the third embodiment of the present disclosure.

A multilayer substrate 301 shown in FIG. 15 has the same structure as the multilayer substrate 1 according to the first embodiment, except for the following points.

The multilayer substrate 301 includes no first electrode 31 and includes a via 302b in the ceramic layer 11, the via 302b being connected to the interlayer connection conductor 50. The intermetallic compound 361 is formed between the interlayer connection conductor 50 and the via 302b.

The ceramic particles 70 are present in the intermetallic compound 361, and the ceramic particles 70 include the first ceramic particles 71 in contact with both the intermetallic compound 361 and the via 302b.

In the multilayer substrate 301, the via 302b functions as a conductor portion.

In the multilayer substrate 301 having such a structure, the presence of the ceramic particles in the intermetallic compound 361 can reduce the difference between the linear expansion coefficient of the intermetallic compound 361 and the linear expansion coefficient of the via 302b. As a result, the thermal stress applied to the intermetallic compound 361 can be reduced. This can prevent fracture of the intermetallic compound 361 due to thermal stress.

Preferred materials of the via 302b are the same as the preferred materials of the first electrodes 31.

Particularly preferably, the via 302b is a fired body of copper (Cu) or an alloy thereof.

### Fourth Embodiment

Next, a multilayer substrate according to a fourth embodiment of the present disclosure is described.

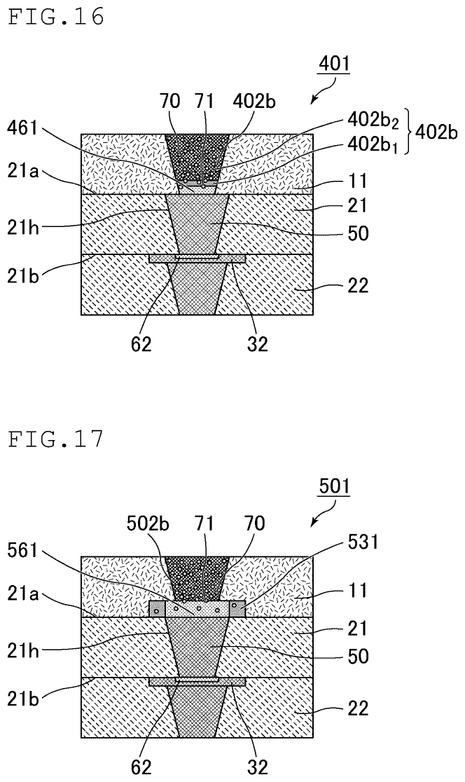

FIG. 16 is a schematic cross-sectional view of an example of an interlayer connection conductor and its surroundings of the multilayer substrate according to the fourth embodiment of the present disclosure.

A multilayer substrate 401 shown in FIG. 16 has the same structure as the multilayer substrate 301 according to the third embodiment, except for the following points.

In the multilayer substrate 401, a via 402b includes a first conductor layer 402b₁ facing the first thermoplastic resin layer 21 and a second conductor layer 402b₂ laminated on the first conductor layer 402b₁.

The weight percentage of the ceramic particles 70 in the first conductor layer 402b₁ is lower than the weight percentage of the ceramic particles 70 in the second conductor layer 402b₂. The first conductor layer 402b₁ may not contain the ceramic particles 70.

When the first conductor layer 402b₁ contains the ceramic particles 70, the ratio of the weight of the ceramic particles 70 in the first conductor layer 402b₁ to the weight of the ceramic particles 70 in the second conductor layer 402b₂, “weight of ceramic particles in first conductor layer/weight of ceramic particles in second conductor layer”, is preferably higher than 0 and 0.7 or lower.

When the interlayer connection conductor 50 and the via 402b are connected by transient liquid phase diffusion bonding, the first conductor layer 402b₁ quickly becomes the intermetallic compound 461 because the weight percentage of the ceramic particles 70 in the first conductor layer 402b₁ is low.

When the intermetallic compound 461 reaches the second conductor layer 402b₂, the second conductor layer 402b₂ is less likely to become the intermetallic compound 461 because the weight percentage of the ceramic particles 70 in the second conductor layer 402b₂ is high.

In other words, the intermetallic compound 461 is less likely to be formed at the boundary between the first conductor layer 402b₁ and the second conductor layer 402b₂.

Although the first conductor layer 402b₁ remains in FIG. 16, the first conductor layer in the multilayer substrate of the present disclosure may entirely be an intermetallic compound.

For this reason, the intermetallic compound 461 can be prevented from diffusing excessively in the thickness direction.

Since the first conductor layer 402b₁ easily becomes the intermetallic compound 461, the interlayer connection conductor 50 and the via 402b can be reliably connected.

Preferred materials of the first conductive layer 402b₁ are the same as the preferred materials of the first conductive layer 231a.

Preferred materials of the second conductive layer 402b₂ are the same as the preferred materials of the second conductive layer 231b.

### Fifth Embodiment

Next, a multilayer substrate according to a fifth embodiment of the present disclosure is described.

FIG. 17 is a schematic cross-sectional view of an example of an interlayer connection conductor and its surroundings of the multilayer substrate according to the fifth embodiment of the present disclosure.

A multilayer substrate 501 shown in FIG. 17 has the same structure as the multilayer substrate 1 according to the first embodiment, except for the following points.

The multilayer substrate 501 includes a via 502b in the ceramic layer 11, the via 502b being connected to a first electrode 531. The first electrode 531 and the via 502b contain the ceramic particles 70.

In the multilayer substrate 501, the weight percentage of the ceramic particles 70 in the first electrode 531 is lower than the weight percentage of the ceramic particles 70 in the via 502b. The first conductor 531 may not contain the ceramic particles 70.

When the first electrode 531 contains the ceramic particles 70, the ratio of the weight of the ceramic particles 70 in the first electrode 531 to the weight of the ceramic particles 70 in the via 502b, “weight of ceramic particles in first electrode/weight of ceramic particles in via”, is preferably higher than 0 and 0.7 or lower.

Preferred materials of the first electrode 531 are the same as the preferred materials of the first conductive layer 231a.

Preferred materials of the via 502b are the same as the preferred materials of the second conductive layer 231b.

In the multilayer substrate 501, the first electrode 531 and the via 502b each function as a conductive portion. The first electrode 531 functions as a first conductor layer, and the via 502b functions as a second conductor layer.

When the interlayer connection conductor 50 and the first electrode 531 are connected by transient liquid phase diffusion bonding, the first electrode 531 quickly becomes the intermetallic compound 561 because the weight percentage of the ceramic particles 70 in the first electrode 531 is low.

When the intermetallic compound 61 reaches the via 502b, the via 502b is less likely to become the intermetallic compound 561 because the weight percentage of the ceramic particles 70 in the second conductor layer 502b₂ is high.

In other words, the intermetallic compound 561 is less likely to be formed at the boundary between the first electrode 531 and the via 502b.

For this reason, the intermetallic compound 561 can be prevented from diffusing excessively in the thickness direction.

Since the first electrode 531 easily becomes the intermetallic compound 561, the interlayer connection conductor 50 and the first electrode 531 can be reliably connected.

The present description discloses the followings.

Disclosed item (1) relates to a multilayer substrate including: a first thermoplastic resin layer including a first main surface, a second main surface opposite to the first main surface, and a via hole penetrating from the first main surface to the second main surface; a ceramic layer in contact with the first main surface; an interlayer connection conductor in the via hole; a conductor portion on the ceramic layer and connected to the interlayer connection conductor; an intermetallic compound between the interlayer connection conductor and the conductor portion; and ceramic particles in the intermetallic compound, wherein the ceramic particles include first ceramic particles in contact with both the intermetallic compound and the conductor portion.

Disclosed item (2) relates to the multilayer substrate according to the disclosed item (1), wherein the intermetallic compound is interposed partially between the first ceramic particles and the conductor portion.

Disclosed item (3) relates to the multilayer substrate according to the disclosed item (1) or (2), wherein a percentage of an area occupied by the ceramic particles in a cross section of the intermetallic compound in a direction perpendicular to the first main surface is 0.1% to 20.0%.

Disclosed item (4) relates to the multilayer substrate according to any one of the disclosed items (1) to (3), wherein in the cross section of the intermetallic compound in the direction perpendicular to the first main surface, when first lines define interfaces between the intermetallic compound and the conductor portion, and second lines define interfaces between the intermetallic compound and the first ceramic particles, a percentage of a total length of the second lines to a total length of the first lines and the second lines is 0.1% to 50.0%.

Disclosed item (5) relates to the multilayer substrate according to any one of the disclosed items (1) to (4), wherein the conductor portion includes the ceramic particles, a first conductor layer facing the first thermoplastic resin layer, and a second conductor layer on the first conductor layer, and a weight percentage of the ceramic particles in the first conductor layer is lower than a weight percentage of the ceramic particles in the second conductor layer.

Disclosed item (6) relates to the multilayer substrate according to any one of the disclosed items (1) to (5), wherein the conductor portion is an electrode.

Disclosed item (7) relates to the multilayer substrate according to any one of the disclosed items (1) to (5), wherein the conductor portion is a via.

Disclosed item (8) relates to the multilayer substrate according to any one of the disclosed items (1) to (7), wherein the ceramic particles include a glass component in an amount of 50% by weight or more.

Disclosed item (9) relates to the multilayer substrate according to any one of the disclosed items (1) to (7), wherein the ceramic particles include alumina in an amount of 50% by mass or more.

Disclosed item (10) relates to the multilayer substrate according to any one of the disclosed items (1) to (9), wherein the ceramic particles are made of a same material as a material of the ceramic layer.

### REFERENCE SIGNS LIST

1, 101, 201, 301, 401, 501 multilayer substrate
2 multilayer ceramic layer
2′ LTCC green sheet laminate
2a, 2a′, 3a electrode pattern
2b, 3b, 302b, 402b, 502b via
3 multilayer thermoplastic resin layer
3a′ metal foil
10, 11 ceramic layer
10′ LTCC green sheet
10h′, 20h, 21h, 22h via hole
20 thermoplastic resin layer
21 first thermoplastic resin layer
21a first main surface of first thermoplastic resin layer
21b second main surface of first thermoplastic resin layer
22 second thermoplastic resin layer
31, 231, 531 first electrode
31′ electrode pattern
31c outline of first electrode
32 second electrode
50 interlayer connection conductor
50′ conductive paste
51 first metal powder
51a liquid phase first metal
52 second metal powder
60, 61, 62, 261, 361, 461, 561 intermetallic compound
70 ceramic particle
70′ unfired ceramic particle
71 first ceramic particle
231a, 402b₁ first conductor layer
231b, 402b₂ second conductor layer

1. A multilayer substrate comprising:
a first thermoplastic resin layer including a first main surface, a second main surface opposite to the first main surface, and a via hole penetrating from the first main surface to the second main surface;
a ceramic layer in contact with the first main surface;
an interlayer connection conductor in the via hole;
a conductor portion on the ceramic layer and connected to the interlayer connection conductor;
an intermetallic compound between the interlayer connection conductor and the conductor portion; and
ceramic particles in the intermetallic compound, wherein the ceramic particles include first ceramic particles in contact with both the intermetallic compound and the conductor portion.

2. The multilayer substrate according to claim 1, wherein the intermetallic compound is interposed partially between the first ceramic particles and the conductor portion.

3. The multilayer substrate according to claim 1, wherein a percentage of an area occupied by the ceramic particles in a cross section of the intermetallic compound in a direction perpendicular to the first main surface is 0.1% to 20.0%.

4. The multilayer substrate according to claim 1, wherein a percentage of an area occupied by the ceramic particles in a cross section of the intermetallic compound in a direction perpendicular to the first main surface is 1.0% to 10.0%.

5. The multilayer substrate according to claim 3, wherein in the cross section of the intermetallic compound in the direction perpendicular to the first main surface, when first lines define interfaces between the intermetallic compound and the conductor portion, and second lines define interfaces between the intermetallic compound and the first ceramic particles, a percentage of a total length of the second lines to a total length of the first lines and the second lines is 0.1% to 50.0%.

6. The multilayer substrate according to claim 1, wherein in a cross section of the intermetallic compound in a direction perpendicular to the first main surface, when first lines define interfaces between the intermetallic compound and the conductor portion, and second lines define interfaces between the intermetallic compound and the first ceramic particles, a percentage of a total length of the second lines to a total length of the first lines and the second lines is 0.1% to 50.0%.

7. The multilayer substrate according to claim 1, wherein in a cross section of the intermetallic compound in a direction perpendicular to the first main surface, when first lines define interfaces between the intermetallic compound and the conductor portion, and second lines define interfaces between the intermetallic compound and the first ceramic particles, a percentage of a total length of the second lines to a total length of the first lines and the second lines is 1.0% to 20.0%.

8. The multilayer substrate according to claim 1,
wherein the conductor portion includes the ceramic particles, a first conductor layer facing the first thermoplastic resin layer, and a second conductor layer on the first conductor layer, and
a weight percentage of the ceramic particles in the first conductor layer is lower than a weight percentage of the ceramic particles in the second conductor layer.

9. The multilayer substrate according to claim 8, wherein a ratio of a weight of the ceramic particles in the first conductor layer to a weight of the ceramic particles in the second conductor layer is higher than 0 and not higher than 0.7.

10. The multilayer substrate according to claim 1, wherein the conductor portion is an electrode.

11. The multilayer substrate according to claim 10, wherein a thickness of the electrode is 5 μm to 20 μm.

12. The multilayer substrate according to claim 1, wherein the conductor portion is a via.

13. The multilayer substrate according to claim 1, wherein the ceramic particles include a glass component in an amount of 50% by weight or more.

14. The multilayer substrate according to claim 1, wherein the ceramic particles include alumina in an amount of 50% by mass or more.

15. The multilayer substrate according to claim 1, wherein the ceramic particles are made of a same material as that of the ceramic layer.

16. The multilayer substrate according to claim 1, wherein the ceramic particles have an average particle size of 0.5 μm to 3 μm.

17. The multilayer substrate according to claim 1,
wherein the conductor portion includes an internal conductor portion in internal of the ceramic layer and an interface conductor portion at an interface of the ceramic layer and the first thermoplastic resin layer, the interface conductor portion and internal conductor portion include the ceramic particles,
the intermetallic compound is formed between the interlayer connection conductor and the interface conductor portion;
the ceramic particles include first ceramic particles in contact with both the intermetallic compound and the interface conductor portion, and
a weight percentage of the ceramic particles in the internal conductor portion is lower than a weight percentage of the ceramic particles in the interface conductor portion.
